(19) United States
(12) Patent Application Publication
(10) Pub. No.: US 2011/0316163 A1
(43) Pub. Date: Dec. 29, 2011

(54) INTEGRATED CIRCUIT PACKAGING SYSTEM WITH MOLDED INTERCONNECTS AND METHOD OF MANUFACTURE THEREOF

(76) Inventors: Byung Tai Do, Singapore (SG); Arnel Senosa Trasporto, Singapore (SG); Linda Pei Ee Chua, Singapore (SG)

(21) Appl. No.: 12/822,877

(22) Filed: Jun. 24, 2010

(51) Int. Cl. H01L 21/56; H01L 23/498

(52) U.S. Cl. 257/773; 438/124; 257/E21.502; 257/E23.06

(57) ABSTRACT

A method of manufacture of an integrated circuit packaging system includes: providing an integrated circuit device; forming package interconnects adjacent the integrated circuit device, the package interconnects having an internal interconnect side with a lock structure; applying an encapsulation over the integrated circuit device and the package interconnects, the lock structure conformally filled with the encapsulation; and forming a base cavity with sides formed by the encapsulation and an external interconnect side of each of an adjacent pair of package interconnects facing one another, the base cavity having a cross-sectional length at least two times a cross-sectional width.

### TECHNICAL FIELD

The present invention relates generally to an integrated circuit packaging system, and more particularly to a system with interconnects.

### BACKGROUND ART

Market growth for high density and high output/input integrated circuit packages has resulted in a trend for electronic products that are lightweight, smaller in size, multi-functional, and capable of ever increasing higher speeds. Products must be capable of competing in world markets and attracting many consumers or buyers.

Electronic products such as cell phone base products, global positioning systems (GPS), satellites, communication equipment, consumer products, and a vast line of other similar products are in ever increasing global demand. It is very important for products to continue to improve in features, performance, and reliability while reducing product costs, product size, and to be available quickly for purchase by the consumers or buyers.

Smaller packages need to be electrically connected with other parts and components. As the smaller packages with more circuits continue to get shrink in size, there is a greater need to produce the smaller packages with more and more package connectors to support continually increasing amounts of electrical connections to and from those smaller packages.

Thus, an increasing need remains to increase the electrical connections of packages as the sizes of the packages continue to shrink in size while the circuits inside those packages continue to increase. It is also critical that the electrical connections are created and placed with precision so that each of the electrical connections can be spaced apart from one another. Smaller packages must be able to connect to circuit boards and deliver increasing functionality, speed, and performance. In view of the economic and technological challenges, it is increasingly critical that answers be found to these problems.

In view of the ever-increasing commercial competitive pressures, along with growing consumer expectations and the diminishing opportunities for meaningful product differentiation in the marketplace, it is critical that answers be found for these problems. Additionally, the need to reduce costs, improve reliability and product yields to meet competitive pressures adds an even greater urgency to the critical necessity for finding answers to these problems.

Solutions to these problems have been long sought after but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing an integrated circuit device; forming package interconnects adjacent the integrated circuit device, the package interconnects having an internal interconnect side with a lock structure; applying an encapsulation over the integrated circuit device and the package interconnects, the lock structure conformally filled with the encapsulation; and forming a base cavity with sides formed by the encapsulation and an external interconnect side of each of an adjacent pair of package interconnects facing one another, the base cavity having a cross-sectional length at least two times a cross-sectional width.

The present invention provides an integrated circuit packaging system, including: an integrated circuit device; package interconnects adjacent the integrated circuit device, the package interconnects having an internal interconnect side with a lock structure; an encapsulation over the integrated circuit device and the package interconnects, the lock structure conformally filled with the encapsulation; and a base cavity with sides formed by the encapsulation and an external interconnect side of each of an adjacent pair of package interconnects facing one another, the base cavity having a cross-sectional length at least two times a cross-sectional width.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in a first embodiment of the present invention.

FIG. 2 is a cross-sectional view of FIG. 1 taken along a line 2-2 of FIG. 1.

FIG. 3 is a cross-sectional view of an integrated circuit packaging system in a second embodiment of the present invention.

FIG. 4 is a cross-sectional view of an integrated circuit packaging system in a third embodiment of the present invention.

FIG. 5 is a cross-sectional view of an integrated circuit packaging system in a fourth embodiment of the present invention.

FIG. 6 is a cross-sectional view of the integrated circuit packaging system of FIG. 2 in an elongated region forming phase.

FIG. 7 is the cross-sectional view of FIG. 6 in an encapsulation phase.

FIG. 8 is a cross-sectional view of the integrated circuit packaging system of FIG. 3 in an elongated region forming phase.

FIG. 9 is the cross-sectional view of FIG. 8 in an encapsulation phase.

FIG. 10 is a cross-sectional view of the integrated circuit packaging system of FIG. 4 in an elongated region forming phase.

FIG. 11 is the cross-sectional view of FIG. 10 in an encapsulation phase.

FIG. 12 is a cross-sectional view of the integrated circuit packaging system of FIG. 5 in an elongated region forming phase.

FIG. 13 is the cross-sectional view of FIG. 12 in an encapsulation phase.

FIG. 14 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown greatly exaggerated in the drawing FIGs. Similarly, although the views in the drawings shown for ease of description and generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the present invention, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is direct contact between elements. The term “directly on” means that there is direct contact between one element and another element without an intervening element.

The term “active side” refers to a side of a die, a module, a package, or an electronic structure having active circuitry fabricated thereon or having elements for connection to the active circuitry within the die, the module, the package, or the electronic structure. The term “processing” as used herein includes deposition of material or photoresist, patterning, exposure, development, etching, cleaning, and/or removal of the material or photoresist as required in forming a described structure.

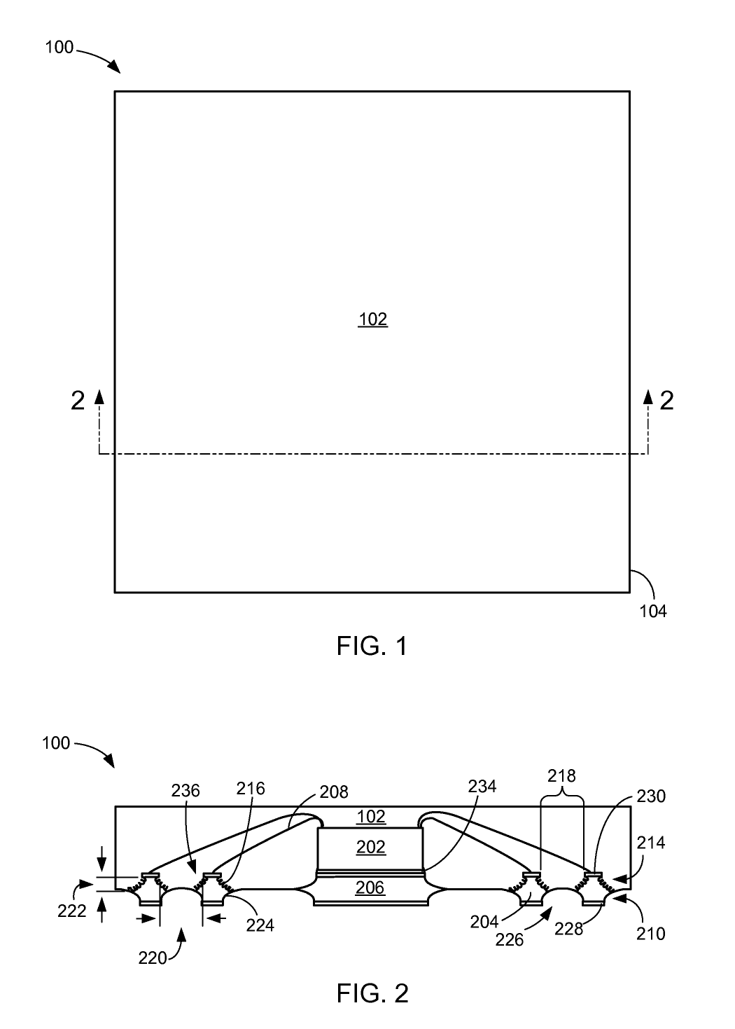

Referring now to FIG. 1, therein is shown a top view of an integrated circuit packaging system 100 in a first embodiment of the present invention. The integrated circuit packaging system 100 is shown with an encapsulation 102 with encapsulation sides 104. The encapsulation 102 is used to protect the integrated circuit packaging system 100 by providing structural support and to hermetically sealing the contents of the integrated circuit packaging system 100.

Referring now to FIG. 2, therein is shown a cross-sectional view of FIG. 1 taken along a line 2-2 of FIG. 1. The integrated circuit packaging system 100 includes an integrated circuit device 202, package interconnects 204, a die pad 206 that is optional, circuit connectors 208, and the encapsulation 102.

The package interconnects 204 can preferably be formed from copper or a copper alloy. The package interconnects 204 can include an external interconnect portion 210 substantially exposed outside the encapsulation 102 and an internal interconnect portion 214 opposite the external interconnect portion 210. The internal interconnect portion 214 is in the encapsulation 102 and includes internal interconnect sides 216.

A cross-section of the internal interconnect sides 216 of a first of the package interconnects 204 facing the internal interconnect sides 216 of a second of the package interconnects 204 without another of the package interconnects 204 intervening can form elongated regions 218. The elongated regions 218 substantially cover the internal interconnect sides 216.

Each of the elongated regions 218 can have a minimum size with a capability to be conformally filled with the encapsulation 102. The elongated regions 218 have an elongated cross-sectional shape that includes a cross-sectional length 220 and a cross-sectional width 222.

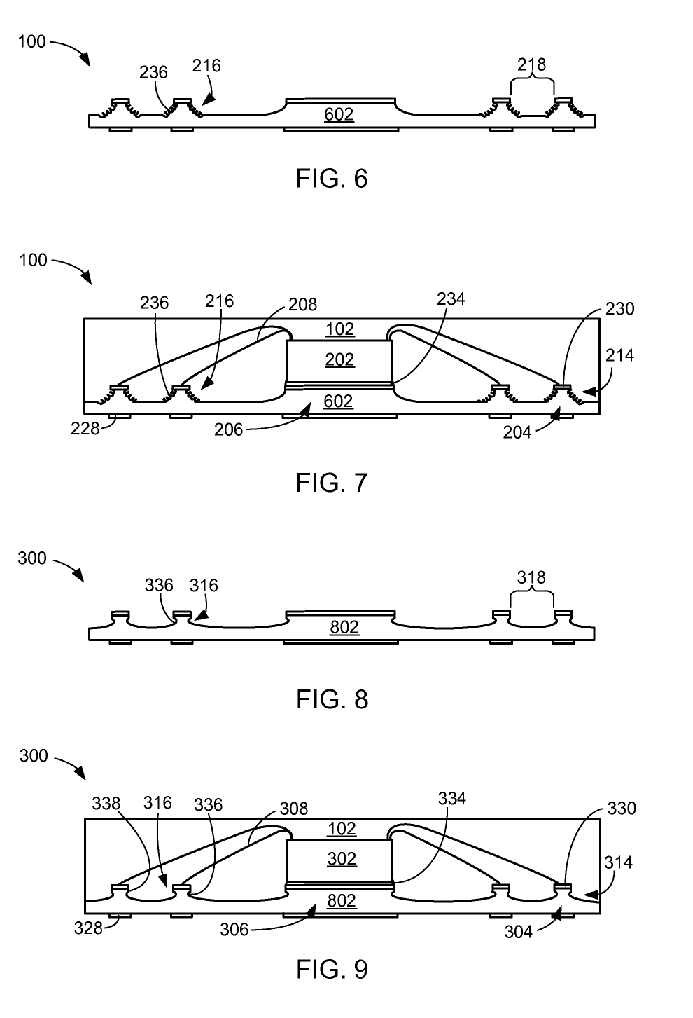

The elongated cross-sectional shape is defined as a cross-sectional shape of an element having a cross-sectional length substantially greater than a cross-sectional width of the element. A ratio of the cross-sectional length 220 to the cross-sectional width 222 can be greater than two to one. The elongated regions 218 can be formed by the multiple step process described in FIG. 6.

The external interconnect portion 210 of the package interconnects 204 can include external interconnect sides 224. The external interconnect portion 210 of each of the package interconnects 204 can be separated from one another and from the die pad 206 by base cavities 226. The base cavities 226 can have any shape and size. The base cavities 226 are formed by the external interconnect sides 224, sides of the die pad 206, and the encapsulation 102 exposed between the package interconnects 204 and around the die pad 206.

The base cavities 226 can be formed in a manner similar to the elongated regions 218 using the multiple step process and have a cross-sectional length and a cross-sectional width the same as the cross-sectional length 220 and the cross-sectional width 222 of the elongated regions 218, respectively.

An external contact layer 228 can be applied on the external interconnect portion 210 and optionally on a side of the die pad 206 facing away from the encapsulation 102. The external contact layer 228 can be used as an etch stop or as a plating for the purposes of attachment to a next level of integration (not shown). The next level of integration can include a printed circuit board, an integrated circuit packaging system, or a combination thereof.

An internal contact layer 230 can be applied on the internal interconnect portion 214 between the elongated regions 218 and optionally on a side of the die pad 206 facing towards the encapsulation 102. The internal contact layer 230 can be used as an etch stop or as a plating for the purposes of attachment.

The integrated circuit device 202 can include a wire bond chip, an integrated circuit module, or any electronic component having integrated circuitry. The integrated circuit device 202 can be mounted over the die pad 206 using an attachment layer 234.

The attachment layer 234 can include an adhesive layer, stacking adhesive, or a combination thereof. The circuit connectors 208, such as bond wires or leads, can be used to connect circuitry of the integrated circuit device 202 with the internal contact layer 230 on the internal interconnect portion 214 to provide electrical connectivity between the circuitry and the external interconnect portion 210 of the package interconnects 204.

The encapsulation 102 can cover the internal contact layer 230, the internal interconnect sides 216 of the package interconnects 204, the integrated circuit device 202, and the circuit connectors 208. The external interconnect portion 210 of each of the circuit connectors 208 face away from the encapsulation 102.

The internal interconnect sides 216 can be formed having a lock structure formed as cavity arrays 236. Openings in the cavity arrays 236 have a minimum size with a capability to be conformally filled with the encapsulation 102. The encapsulation 102 adhering to the cavity arrays 236 in the internal interconnect sides 216 and the elongated regions 218 prevent movement between the package interconnects 204 and the encapsulation 102 and to provide structural rigidity to the present invention.

The cavity arrays 236 provide a roughened surface such as the result of a surface etch roughening. The roughened surface is the result of a patterned plurality of the lock structure creating an uneven surface with alternating openings and unetched portions. The patterned plurality provides a multitude of openings for locking the package interconnects 204 to the encapsulation 102.

It has been discovered that the elongated regions 218 and the base cavities 226, both formed with the cross-sectional length 220 at least two times the cross-sectional width 222, enable the package interconnects 204 to be formed having a z-height smaller than a z-height of terminals in typical quad flat no lead package with standoff terminals (QFNs-ST).

It has been discovered that the cavity arrays 236 and the elongated regions 218 provide the integrated circuit packaging system 100 with structural integrity eliminating lead fall-off, missing leads, or lead pull-out problems.

It has been unexpectedly found that the cavity arrays 236 can be formed around the bonding areas including the internal contact layer 230 and the external contact layer 228 of the package interconnects 204, without reducing or compromising available electrical attachment area of the bonding areas.

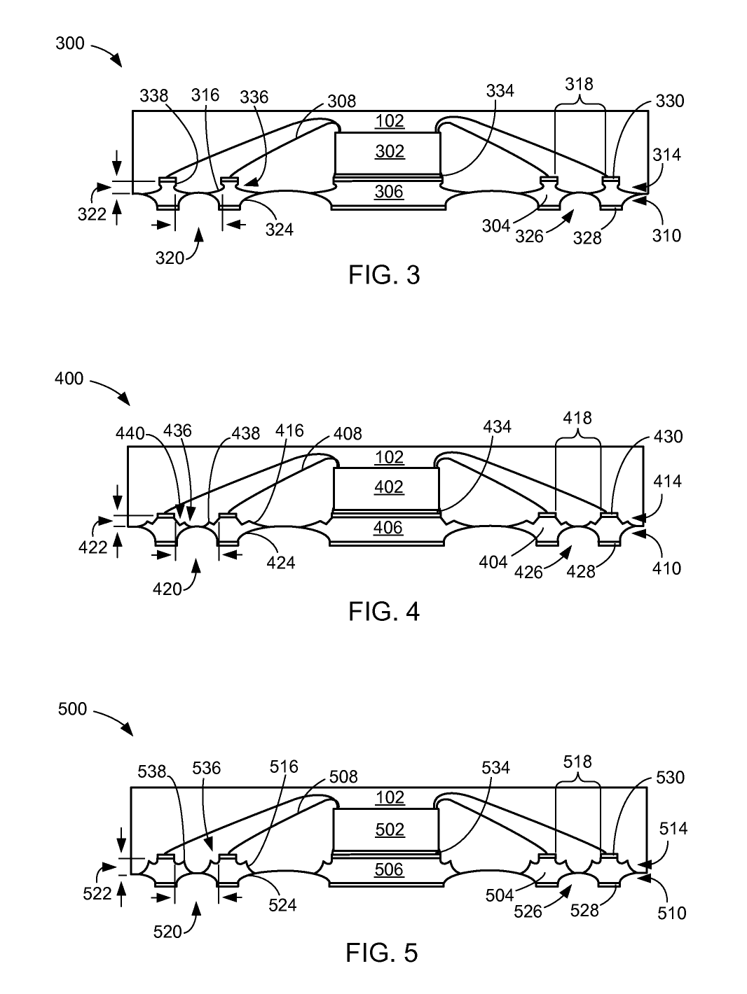

Referring now to FIG. 3, therein is shown a cross-sectional view of an integrated circuit packaging system in a second embodiment of the present invention. The integrated circuit packaging system 300 includes an integrated circuit device 302, package interconnects 304, a die pad 306 that is optional, circuit connectors 308, and the encapsulation 102.

The package interconnects 304 can preferably be formed from copper or a copper alloy. The package interconnects 304 can include an external interconnect portion 310 substantially exposed outside the encapsulation 102 and an internal interconnect portion 314 opposite the external interconnect portion 310. The internal interconnect portion 314 is in the encapsulation 102 and includes internal interconnect sides 316.

A cross-section of the internal interconnect sides 316 of a first of the package interconnects 304 facing the internal interconnect sides 316 of a second of the package interconnects 304 without another of the package interconnects 304 intervening can form elongated regions 318. The elongated regions 318 substantially cover the internal interconnect sides 316.

Each of the elongated regions 318 can have a minimum size with a capability to be conformally filled with the encapsulation 102. The elongated regions 318 have an elongated cross-sectional shape that includes a cross-sectional length 320 and a cross-sectional width 322.

The elongated cross-sectional shape is defined as a cross-sectional shape of an element having a cross-sectional length substantially greater than a cross-sectional width of the element. A ratio of the cross-sectional length 320 to the cross-sectional width 322 can be greater than two to one. The elongated regions 318 can be formed by the multiple step process described in FIG. 8.

The external interconnect portion 310 of the package interconnects 304 can include external interconnect sides 324. The external interconnect portion 310 of each of the package interconnects 304 can be separated from one another and from the die pad 306 by base cavities 326. The base cavities 326 can have any shape and size. The base cavities 326 are formed by the external interconnect sides 324, sides of the die pad 306, and the encapsulation 102 exposed between the package interconnects 304 and around the die pad 306.

An external contact layer 328 can be applied on the external interconnect portion 310 and optionally on a side of the die pad 306 facing away from the encapsulation 102. The external contact layer 328 can be used as an etch stop or as a plating for the purposes of attachment to a next level of integration (not shown). The next level of integration can include a printed circuit board, an integrated circuit packaging system, or a combination thereof.

An internal contact layer 330 can be applied on the internal interconnect portion 314 between the elongated regions 318 and optionally on a side of the die pad 306 facing towards the encapsulation 102. The internal contact layer 330 can be used as an etch stop or as a plating for the purposes of attachment to circuitry of the integrated circuit device 302.

The integrated circuit device 302 can include a wire bond chip, an integrated circuit module, or any electronic component having integrated circuitry. The integrated circuit device 302 can be mounted over the die pad 306 using an attachment layer 334.

The attachment layer 334 can include an adhesive layer, stacking adhesive, or a combination thereof. The circuit connectors 308, such as bond wires or leads, can be used to connect circuitry of the integrated circuit device 302 with the internal contact layer 330 on the internal interconnect portion 314 to provide electrical connectivity between the circuitry and the external interconnect portion 310 of the package interconnects 304.

The encapsulation 102 can cover the internal contact layer 330, the internal interconnect sides 316 of the package interconnects 304, the integrated circuit device 302, and the circuit connectors 308. The external interconnect portion 310 of each of the circuit connectors 308 face away from the encapsulation 102.

The internal interconnect sides 316 can be formed having a lock structure formed as a pocket cavity 336 at an end of the internal interconnect sides 316 covered by the internal contact layer 330. The pocket cavity 336 has an opening with a minimum size with a capability to be conformally filled with the encapsulation 102.

The internal interconnect sides 316 are formed having an extension 338 with a non-horizontal end. The extension 338 is preferably cantilevered over the encapsulation 102 in the pocket cavity 336. The extension 338 between the pocket cavity 336 and the internal contact layer 330 increases the surface area of the internal interconnect sides 316 in contact with the encapsulation 102, surrounded by, and confining the encapsulation 102 from escaping from within the pocket cavity 336.

The encapsulation 102 adhering to the pocket cavity 336, confined within the pocket cavity 336, and attached to an increased surface area of the internal interconnect sides 316 prevents movement between the package interconnects 304 and the encapsulation 102 and to provide structural rigidity to the present invention.

It has been discovered that the elongated regions 318 and the base cavities 326, both formed with the cross-sectional length 320 at least two times the cross-sectional width 322, enable the package interconnects 304 to be formed having a z-height smaller than a z-height of terminals in typical quad flat no lead package with standoff terminals (QFNs-ST).

It has been discovered that the pocket cavity 336 and the elongated regions 318 provide the integrated circuit packaging system 300 with structural integrity eliminating lead fall-off, missing leads, or lead pull-out problems.

It has been unexpectedly found that the pocket cavity 336 can be formed around the bonding areas including the internal contact layer 330 and the external contact layer 328 of the package interconnects 304, without reducing or compromising available electrical attachment area of the bonding areas.

Referring now to FIG. 4, therein is shown a cross-sectional view of an integrated circuit packaging system in a third embodiment of the present invention. The integrated circuit packaging system 400 includes an integrated circuit device 402, package interconnects 404, a die pad 406 that is optional, circuit connectors 408, and the encapsulation 102.

The package interconnects 404 can preferably be formed from copper or a copper alloy. The package interconnects 404 can include an external interconnect portion 410 substantially exposed outside the encapsulation 102 and an internal interconnect portion 414 opposite the external interconnect portion 410. The internal interconnect portion 414 is in the encapsulation 102 and includes internal interconnect sides 416.

A cross-section of the internal interconnect sides 416 of a first of the package interconnects 404 facing the internal interconnect sides 416 of a second of the package interconnects 404 without another of the package interconnects 404 intervening can form elongated regions 418. The elongated regions 418 substantially cover the internal interconnect sides 416.

Each of the elongated regions 418 can have a minimum size with a capability to be conformally filled with the encapsulation 102. The elongated regions 418 have an elongated cross-sectional shape that includes a cross-sectional length 420 and a cross-sectional width 422.

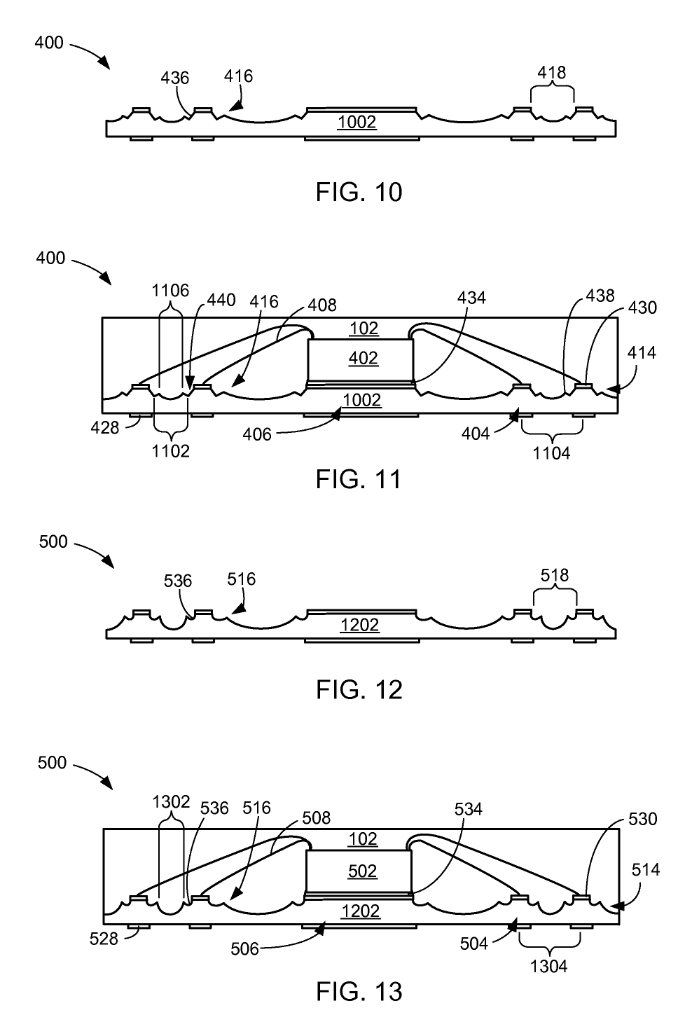

The elongated cross-sectional shape is defined as a cross-sectional shape of an element having a cross-sectional length substantially greater than a cross-sectional width of the element. A ratio of the cross-sectional length 420 to the cross-sectional width 422 can be greater than two to one. The elongated regions 418 can be formed by the multiple step process described in FIG. 10.

The external interconnect portion 410 of the package interconnects 404 can include external interconnect sides 424. The external interconnect portion 410 of each of the package interconnects 404 can be separated from one another and from the die pad 406 by base cavities 426. The base cavities 426 can have any shape and size. The base cavities 426 are formed by the external interconnect sides 424, sides of the die pad 406, and the encapsulation 102 exposed between the package interconnects 404 and around the die pad 406.

The base cavities 426 can be formed in a manner similar to the elongated regions 418 using the multiple step process and have a cross-sectional length and a cross-sectional width substantially similar to the cross-sectional length 420 and the cross-sectional width 422 of the elongated regions 418, respectively.

An external contact layer 428 can be applied on the external interconnect portion 410 and optionally on a side of the die pad 406 facing away from the encapsulation 102. The external contact layer 428 can be used as an etch stop or as a plating for the purposes of attachment to a next level of integration (not shown). The next level of integration can include a printed circuit board, an integrated circuit packaging system, or a combination thereof.

An internal contact layer 430 can be applied on the internal interconnect portion 414 between the elongated regions 418 and optionally on a side of the die pad 406 facing towards the encapsulation 102. The internal contact layer 430 can be used as an etch stop or as a plating for the purposes of attachment to circuitry of the integrated circuit device 402.

The integrated circuit device 402 can include a wire bond chip, an integrated circuit module, or any electronic component having integrated circuitry. The integrated circuit device 402 can be mounted over the die pad 406 using an attachment layer 434.

The attachment layer 434 can include an adhesive layer, stacking adhesive, or a combination thereof. The circuit connectors 408, such as bond wires or leads, can be used to connect circuitry of the integrated circuit device 402 with the internal contact layer 430 on the internal interconnect portion 414 to provide electrical connectivity between the circuitry and the external interconnect portion 410 of the package interconnects 404.

The encapsulation 102 can cover the internal contact layer 430, the internal interconnect sides 416 of the package interconnects 404, the integrated circuit device 402, and the circuit connectors 408. The external interconnect portion 410 of each of the circuit connectors 408 face away from the encapsulation 102.

The internal interconnect sides 416 can be formed having a lock structure formed as cavities 436 with protrusions 438 and crevices 440. The crevices 440 have a cross-sectional shape of an angular shaped corner. The protrusions 438 are raised sides separating the cavities 436 from the crevices 440. The cavities 436 and the protrusions 438 increase the surface area of the internal interconnect sides 416 in contact with the encapsulation 102 to improve adhesive characteristics.

The crevices 440 having a minimum size with a capability to be conformally filled with the encapsulation 102 to prevent movement between the package interconnects 404 and the encapsulation 102 and to provide structural rigidity to the present invention. The protrusions 438 are surrounded and in contact with the encapsulation 102 to prevent movement between the package interconnects 404 and the encapsulation 102 and to provide structural rigidity to the present invention.

It has been discovered that the elongated regions 418 and the base cavities 426, both formed with the cross-sectional length 420 at least two times the cross-sectional width 422, enable the package interconnects 404 to be formed having a z-height smaller than a z-height of terminals in typical quad flat no lead package with standoff terminals (QFNs-ST).

It has been discovered that the cavities 436 and the elongated regions 418 provide the integrated circuit packaging system 400 with structural integrity eliminating lead fall-off, missing leads, or lead pull-out problems.

It has been unexpectedly found that the cavities 436 can be formed around the bonding areas including the internal contact layer 430 and the external contact layer 428 of the package interconnects 404, without reducing or compromising available electrical attachment area of the bonding areas.

Referring now to FIG. 5, therein is shown a cross-sectional view of an integrated circuit packaging system in a fourth embodiment of the present invention. The integrated circuit packaging system 500 includes an integrated circuit device 502, package interconnects 504, a die pad 506 that is optional, circuit connectors 508, and the encapsulation 102.

The package interconnects 504 can preferably be formed from copper or a copper alloy. The package interconnects 504 can include an external interconnect portion 510 substantially exposed outside the encapsulation 102 and an internal interconnect portion 514 opposite the external interconnect portion 510. The internal interconnect portion 514 is in the encapsulation 102 and includes internal interconnect sides 516.

A cross-section of the internal interconnect sides 516 of a first of the package interconnects 504 facing the internal interconnect sides 516 of a second of the package interconnects 504 without another of the package interconnects 504 intervening can form elongated regions 518. The elongated regions 518 substantially cover the internal interconnect sides 516.

Each of the elongated regions 518 can have a minimum size with a capability to be conformally filled with the encapsulation 102. The elongated regions 518 have an elongated cross-sectional shape that includes a cross-sectional length 520 and a cross-sectional width 522.

The elongated cross-sectional shape is defined as a cross-sectional shape of an element having a cross-sectional length substantially greater than a cross-sectional width of the element. A ratio of the cross-sectional length 520 to the cross-sectional width 522 can be greater than two to one. The elongated regions 518 can be formed by the multiple step process described in FIG. 12.

The external interconnect portion 510 of the package interconnects 504 can include external interconnect sides 524. The external interconnect portion 510 of each of the package interconnects 504 can be separated from one another and from the die pad 506 by base cavities 526. The base cavities 526 can have any shape and size. The base cavities 526 are formed by the external interconnect sides 524, sides of the die pad 506, and the encapsulation 102 exposed between the package interconnects 504 and around the die pad 506.

An external contact layer 528 can be applied on the external interconnect portion 510 and optionally on a side of the die pad 506 facing away from the encapsulation 102. The external contact layer 528 can be used as an etch stop or as a plating for the purposes of attachment to a next level of integration (not shown). The next level of integration can include a printed circuit board, an integrated circuit packaging system, or a combination thereof.

An internal contact layer 530 can be applied on the internal interconnect portion 514 between the elongated regions 518 and optionally on a side of the die pad 506 facing towards the encapsulation 102. The internal contact layer 530 can be used as an etch stop or as a plating for the purposes of attachment to circuitry of the integrated circuit device 502.

The integrated circuit device 502 can include a wire bond chip, an integrated circuit module, or any electronic component having integrated circuitry. The integrated circuit device 502 can be mounted over the die pad 506 using an attachment layer 534.

The attachment layer 534 can include an adhesive layer, stacking adhesive, or a combination thereof. The circuit connectors 508, such as bond wires or leads, can be used to connect circuitry of the integrated circuit device 502 with the internal contact layer 530 on the internal interconnect portion 514 to provide electrical connectivity between the circuitry and the external interconnect portion 510 of the package interconnects 504.

The encapsulation 102 can cover the internal contact layer 530, the internal interconnect sides 516 of the package interconnects 504, the integrated circuit device 502, and the circuit connectors 508. The external interconnect portion 510 of each of the circuit connectors 508 face away from the encapsulation 102.

The internal interconnect sides 516 can be formed having a lock structure formed as concave indentations 536 and ridges 538 formed around the concave indentations 536. The ridges 538 can also be formed on facing pairs of the concave indentations 536 or around any or all sides of any of the package interconnects 504. The concave indentations 536 increases the surface area of the internal interconnect sides 516 and enables the encapsulation 102 to penetrate into the concave indentations 536 to improve adhesive characteristics.

The ridges 538 extend into the encapsulation 102 to increase the surface area of the internal interconnect sides 516 and to anchor the internal interconnect sides 516 to the encapsulation 102 to prevent movement between the package interconnects 504 and the encapsulation 102 and to provide structural rigidity to the present invention.

It has been discovered that the elongated regions 518 and the base cavities 526, both formed with the cross-sectional length 520 at least two times the cross-sectional width 522, enable the package interconnects 504 to be formed having a z-height smaller than a z-height of terminals in typical quad flat no lead package with standoff terminals (QFNs-ST).

It has been discovered that the concave indentations 536 and the elongated regions 518 provide the integrated circuit packaging system 500 with structural integrity eliminating lead fall-off, missing leads, or lead pull-out problems.

It has been unexpectedly found that the concave indentations 536 can be formed around the bonding areas including the internal contact layer 530 and the external contact layer 528 of the package interconnects 504, without reducing or compromising available electrical attachment area of the bonding areas.

Referring now to FIG. 6, therein is shown a cross-sectional view of the integrated circuit packaging system 100 of FIG. 2 in an elongated region forming phase. Shown is a leadframe 602 having the internal interconnect sides 216 with the cavity arrays 236. The internal interconnect sides 216 and the cavity arrays 236 can be formed using an etching process or an electro discharge machining (EDM) process, which can provide intricate shapes in high accuracy such as one micron or one ten thousandths of a millimeter.

The elongated regions 218 can be formed using a multiple step process that can include etching, electro discharge machining, other removal processes, or combination thereof. The multiple step process preferably includes applying a barrier (not shown) on a portion of a cavity in a previously processed surface of the leadframe 602 to prevent further removal of material in the portion of the cavity.

It has been discovered that the multiple step process enables formation of the elongated regions 218 and the base cavities 226 of FIG. 2. The shape of the elongated regions 218 and the base cavities 226 enables the formation of the lock structure and the electrical separation of the package interconnects 204 of FIG. 2.

Referring now to FIG. 7, therein is shown the cross-sectional view of FIG. 6 in an encapsulation phase. The integrated circuit device 202 can include a wire bond chip, an integrated circuit module, or any electronic component having integrated circuitry. The integrated circuit device 202 can be mounted over the die pad 206 using the attachment layer 234.

The circuit connectors 208 can be used to connect circuitry of the integrated circuit device 202 with the internal contact layer 230 on the internal interconnect portion 214 of the package interconnects 204 to provide electrical connectivity. The encapsulation 102 can cover the internal contact layer 230, the internal interconnect sides 216 of the package interconnects 204, the integrated circuit device 202, and the circuit connectors 208.

The base cavities 226 of FIG. 2 can be formed by etching regions around the external contact layer 228 on the leadframe 602 to expose the encapsulation 102, to isolate the package interconnects 204 from one another. Etching the regions provides the integrated circuit packaging system 100 of FIG. 2.

Referring now to FIG. 8, therein is shown a cross-sectional view of the integrated circuit packaging system of FIG. 3 in an elongated region forming phase. Shown is a leadframe 802 having the internal interconnect sides 316 with the pocket cavity 336. The internal interconnect sides 316 and the pocket cavity 336 can be formed using an etching process or an electro discharge machining (EDM) process, which can provide intricate shapes in high accuracy such as one micron or one ten thousandths of a millimeter.

The elongated regions 318 can be formed using a multiple step process that can include etching, electro discharge machining, other removal processes, or combination thereof. The multiple step process preferably includes applying a barrier (not shown) on a portion of a cavity in a previously processed surface of the leadframe 802 to prevent further removal of material in the portion of the cavity.

Referring now to FIG. 9, therein is shown the cross-sectional view of FIG. 8 in an encapsulation phase. The integrated circuit device 302 can include a wire bond chip, an integrated circuit module, or any electronic component having integrated circuitry. The integrated circuit device 302 can be mounted over the die pad 306 using the attachment layer 334.

The circuit connectors 308 can be used to connect circuitry of the integrated circuit device 302 with the internal contact layer 330 on the internal interconnect portion 314 to provide electrical connectivity. The encapsulation 102 can cover the internal contact layer 330, the internal interconnect sides 316 of the package interconnects 304, the integrated circuit device 302, and the circuit connectors 308.

The base cavities 326 of FIG. 3 can be formed by etching regions around the external contact layer 328 on the leadframe 802 to expose the encapsulation 102, to isolate the package interconnects 304 from one another. Etching the regions provides the integrated circuit packaging system 300 of FIG. 3.

Referring now to FIG. 10, therein is shown a cross-sectional view of the integrated circuit packaging system of FIG. 4 in an elongated region forming phase. Shown is a leadframe 1002 having the internal interconnect sides 416 with the cavities 436. The internal interconnect sides 416 and the cavities 436 can be formed using an etching process or an electro discharge machining (EDM) process, which can provide intricate shapes in high accuracy such as one micron or one ten thousandths of a millimeter.

The elongated regions 418 can be formed using a multiple step process that can include etching, electro discharge machining, other removal processes, or combination thereof. The multiple step process preferably includes applying a barrier (not shown) on a portion of a cavity in a previously processed surface of the leadframe 1002 to prevent further removal of material in the portion of the cavity.

It has been discovered that the multiple step process enables formation of the elongated regions 418 and the base cavities 426 of FIG. 4. The shape of the elongated regions 418 and the base cavities 426 enables the formation of the lock structure and the electrical separation of the package interconnects 404 of FIG. 4.

Referring now to FIG. 11, therein is shown the cross-sectional view of FIG. 10 in an encapsulation phase. The integrated circuit device 402 can include a wire bond chip, an integrated circuit module, or any electronic component having integrated circuitry. The integrated circuit device 402 can be mounted over the die pad 406 using the attachment layer 434.

The circuit connectors 408 can be used to connect circuitry of the integrated circuit device 402 with the internal contact layer 430 on the internal interconnect portion 414 to provide electrical connectivity. The encapsulation 102 can cover the internal contact layer 430, the internal interconnect sides 416 of the package interconnects 404, the integrated circuit device 402, and the circuit connectors 408.

The base cavities 426 of FIG. 4 can be formed by etching regions around the external contact layer 428 on the leadframe 1002 to expose the encapsulation 102, to isolate the package interconnects 404 from one another. Etching the regions provides the integrated circuit packaging system 400 of FIG. 4.

As an example, the electro discharge machining (EDM) process can form the crevices 440 between two of the internal interconnect portion 414 facing each other, the crevices 440 with a crevice pitch 1102 of approximately two hundred five thousandths millimeter. The crevice pitch 1102 is based on an interconnect pitch 1104 of five hundred fifty thousandths millimeter.

As an example, EDM process can form the protrusions 438 between two of the internal interconnect portion 414 facing each other, the protrusions 438 with a protrusion pitch 1106 of approximately two hundred five thousandths millimeter. The protrusion pitch 1106 is based on the interconnect pitch 1104 of five hundred fifty thousandths millimeter.

Referring now to FIG. 12, therein is shown a cross-sectional view of the integrated circuit packaging system of FIG. 5 in an elongated region forming phase. Shown is a leadframe 1202 having the internal interconnect sides 516 with the concave indentations 536. The internal interconnect sides 516 and the concave indentations 536 can be formed using an etching process or an electro discharge machining (EDM) process, which can provide intricate shapes in high accuracy such as one micron or one ten thousandths of a millimeter.

The elongated regions 518 can be formed using a multiple step process that can include etching, electro discharge machining, other removal processes, or combination thereof. The multiple step process preferably includes applying a barrier (not shown) on a portion of a cavity in a previously processed surface of the leadframe 1202 to prevent further removal of material in the portion of the cavity. The elongated regions 518 can be formed using a multiple step process that can include etching, electro discharge machining, other removal processes, or combination thereof.

Referring now to FIG. 13, therein is shown the cross-sectional view of FIG. 12 in an encapsulation phase. The integrated circuit device 502 can include a wire bond chip, an integrated circuit module, or any electronic component having integrated circuitry. The integrated circuit device 502 can be mounted over the die pad 506 using the attachment layer 534.

The circuit connectors 508 can be used to connect circuitry of the integrated circuit device 502 with the internal contact layer 530 on the internal interconnect portion 514 to provide electrical connectivity. The encapsulation 102 can cover the internal contact layer 530, the internal interconnect sides 516 of the package interconnects 504, the integrated circuit device 502, and the circuit connectors 508.

The base cavities 526 of FIG. 5 can be formed by etching regions around the external contact layer 528 on the leadframe 1202 to expose the encapsulation 102, to isolate the package interconnects 504 from one another. Etching the regions provides the integrated circuit packaging system 500 of FIG. 5.

As an example, the electro discharge machining (EDM) process can form the concave indentations 536 between two of the internal interconnect portion 514 facing each other, the concave indentations 536 with an indentation pitch 1302 of approximately one hundred and eighty thousandths millimeter. The indentation pitch 1302 is based on an interconnect pitch 1304 of five hundred fifty thousandths millimeter.

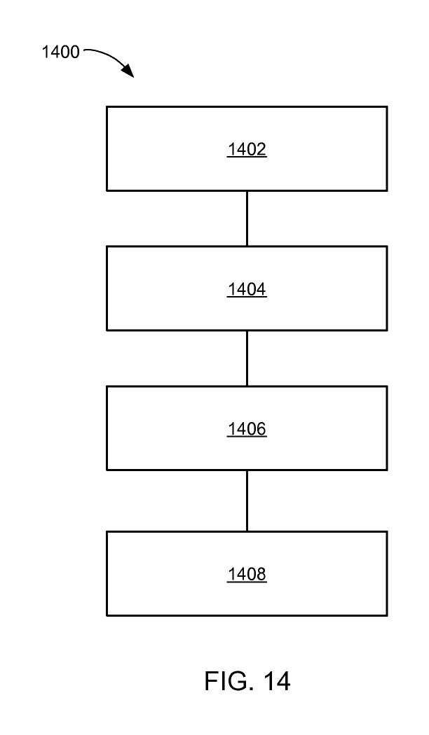

Referring now to FIG. 14, therein is shown is a flow chart of a method 1400 of manufacture of the integrated circuit packaging system 100 in a further embodiment of the present invention. The method 1400 includes: providing an integrated circuit device in a block 1402; forming package interconnects adjacent the integrated circuit device, the package interconnects having an internal interconnect side with a lock structure in a block 1404; applying an encapsulation over the integrated circuit device and the package interconnects, the lock structure conformally filled with the encapsulation in a block 1406; and forming a base cavity with sides formed by the encapsulation and an external interconnect side of each of an adjacent pair of package interconnects facing one another, the base cavity having a cross-sectional length at least two times a cross-sectional width in a block 1408.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing package in package systems/fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the a foregoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing an integrated circuit device;
forming package interconnects adjacent the integrated circuit device, the package interconnects having an internal interconnect side with a lock structure;
applying an encapsulation over the integrated circuit device and the package interconnects, the lock structure conformally filled with the encapsulation; and
forming a base cavity with sides formed by the encapsulation and an external interconnect side of each of an adjacent pair of package interconnects facing one another, the base cavity having a cross-sectional length at least two times a cross-sectional width.

2. The method as claimed in claim 1 further comprising applying an internal contact layer on the package interconnects for attachment of connectors to the integrated circuit device to the encapsulation.

3. The method as claimed in claim 1 wherein forming the package interconnects includes forming the package interconnects with an extension cantilevered over the lock structure for locking the package interconnects to the encapsulation.

4. The method as claimed in claim 1 wherein forming the package interconnects includes forming the lock structure with a protrusion for locking the package interconnects to the encapsulation.

5. The method as claimed in claim 1 wherein forming the package interconnects includes forming the lock structure with a ridge across the internal interconnect side, the ridge extended into the encapsulation for locking the package interconnects to the encapsulation.

6. A method of manufacture of an integrated circuit packaging system comprising:
providing an integrated circuit device;
forming package interconnects adjacent the integrated circuit device, the package interconnects having an internal interconnect side with a lock structure;
attaching circuit connectors to the integrated circuit device and package interconnects;
applying an encapsulation over the integrated circuit device and the package interconnects, the lock structure conformally filled with the encapsulation; and
forming a base cavity with sides formed by the encapsulation and an external interconnect side of each of an adjacent pair of package interconnects facing one another, the base cavity having a cross-sectional length at least two times a cross-sectional width.

7. The method as claimed in claim 6 further comprising applying an external contact layer on the package interconnects for the purposes of attachment.

8. The method as claimed in claim 6 wherein forming the package interconnects includes forming the package interconnects with an extension cantilevered over the encapsulation in the lock structure for locking the package interconnects to the encapsulation.

9. The method as claimed in claim 6 wherein forming the package interconnects includes forming the lock structure with a crevice for locking the package interconnects to the encapsulation for locking the package interconnects to the encapsulation.

10. The method as claimed in claim 6 wherein forming the package interconnects includes forming the concave indentation with a ridge across the internal interconnect side, the ridge extended into the encapsulation to prevent movement between the package interconnects and the encapsulation.

11. An integrated circuit packaging system comprising:
an integrated circuit device;
package interconnects adjacent the integrated circuit device, the package interconnects having an internal interconnect side with a lock structure;
an encapsulation over the integrated circuit device and the package interconnects, the lock structure conformally filled with the encapsulation; and
a base cavity with sides formed by the encapsulation and an external interconnect side of each of an adjacent pair of package interconnects facing one another, the base cavity having a cross-sectional length at least two times a cross-sectional width.

12. The system as claimed in claim 11 further comprising an internal contact layer on the package interconnects for attachment of connectors to the integrated circuit device to the encapsulation.

13. The system as claimed in claim 11 wherein the package interconnects includes the package interconnects formed with an extension cantilevered over the lock structure for locking the package interconnects to the encapsulation.

14. The system as claimed in claim 11 wherein the package interconnects includes the lock structure formed with a protrusion for locking the package interconnects to the encapsulation.

15. The system as claimed in claim 11 wherein the package interconnects includes the lock structure formed with a ridge across the internal interconnect side, the ridge extended into the encapsulation for locking the package interconnects to the encapsulation.

16. The system as claimed in claim 11 further comprising circuit connectors attached to the integrated circuit device and package interconnects.

17. The system as claimed in claim 16 further comprising an external contact layer on the package interconnects for the purposes of attachment.

18. The method as claimed in claim 16 wherein the package interconnects includes the package interconnects formed with an extension cantilevered over the encapsulation in the lock structure for locking the package interconnects to the encapsulation.

19. The system as claimed in claim 16 wherein the package interconnects includes the lock structure formed with a crevice for locking the package interconnects to the encapsulation.

20. The system as claimed in claim 16 wherein the package interconnects includes the concave indentation formed with a ridge across the internal interconnect side, the ridge extended into the encapsulation to prevent movement between the package interconnects and the encapsulation.
